(19) United States
(12) Patent Application Publication
(10) Pub. No.: US 2025/0203897 A1
(43) Pub. Date: Jun. 19, 2025

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventor: Nobutaka OI, Kyoto-shi (JP)

(73) Assignee: ROHM CO., LTD., Kyoto-shi (JP)

(21) Appl. No.: 19/073,075

(22) Filed: Mar. 7, 2025

Related U.S. Application Data
(63) Continuation of application No. PCT/JP2023/030989, filed on Aug. 28, 2023.

(30) Foreign Application Priority Data
Sep. 9, 2022 (JP) 2022-143915

(51) Int. Cl. H10D 12/00; H10D 12/01; H10D 62/10; H10D 64/23; H10D 64/27; H10D 64/66

(52) U.S. Cl. CPC H10D 12/481; H10D 12/038; H10D 62/102; H10D 64/232; H10D 64/516; H10D 64/519; H10D 64/661

(57) ABSTRACT

A semiconductor device including a gate electrode embedded in a gate trench, a surface insulating layer formed on a first principal surface and having a contact hole, a covering insulating layer covering the gate electrode in the gate trench and insulating the gate electrode and the contact electrode from each other, and an embedded body embedded in a region on the covering insulating layer in the gate trench and having an etching selectivity to the surface insulating layer.

### CROSS-REFERENCE TO RELATED APPLICATIONS

The present application is a bypass continuation of International Patent Application No. PCT/JP2023/030989 filed on Aug. 28, 2023, which corresponds to Japanese Patent Application No. 2022-143915 filed on Sep. 9, 2022, in the Japan Patent Office, and the entire disclosure of these applications are incorporated herein by reference.

### TECHNICAL FIELD

The present disclosure relates to a semiconductor device and a manufacturing method therefor.

### BACKGROUND ART

Patent Literature 1 (WO 2019/103135) discloses a semiconductor device that includes a semiconductor layer that has a principal surface in which a trench is formed, a body region of a first conductivity type formed along a side wall of the trench in a surface layer portion of the principal surface of the semiconductor layer, an impurity region formed of a second conductivity type along the side wall of the trench in a surface layer portion of the body region, a gate insulating layer formed on an inner wall of the trench, a gate electrode that is embedded in the trench and faces the body region and the impurity region across the gate insulating layer, a contact electrode that passes through the side wall of the trench from inside the trench and is led out to the surface layer portion of the principal surface of the semiconductor layer and is electrically connected to the body region and the impurity region, and an embedded insulating layer that is interposed between the gate electrode and the contact electrode in the trench and insulates the gate electrode and the contact electrode.

### BRIEF DESCRIPTION OF DRAWINGS

FIG. 1 is a schematic cross-sectional perspective view illustrating a partial region of a semiconductor device according to a first preferred embodiment of the present disclosure.

FIG. 2 is a diagram in which the structure on a first principal surface of a chip is removed from FIG. 1.

FIG. 3 is a view in which an emitter contact electrode layer is removed from FIG. 2.

FIG. 4 is a schematic plan view of FIG. 3 as viewed from the first principal surface of the chip.

FIG. 5 is a cross-sectional view taken along line V-V illustrated in FIG. 4.

FIG. 6 is a cross-sectional view taken along line VI-VI illustrated in FIG. 4.

FIG. 7 is a cross-sectional perspective view taken along VII-VII illustrated in FIG. 3.

FIG. 8 is a cross-sectional view taken along line VIII-VIII illustrated in FIG. 4.

FIG. 9 is an enlarged view of a portion surrounded by an alternate long and two short dashed line IX in FIG. 6.

FIGS. 10A and 10B are diagrams illustrating part of the manufacturing process of a semiconductor device.

FIGS. 11A and 11B are diagrams illustrating steps after FIGS. 10A and 10B, respectively.

FIG. 12A and FIG. 12B are views illustrating steps after FIG. 11A and FIG. 11B, respectively.

FIGS. 13A and 13B are views illustrating steps after FIGS. 12A and 12B, respectively.

FIGS. 14A and 14B are diagrams illustrating steps after FIGS. 13A and 13B, respectively.

FIGS. 15A and 15B are diagrams illustrating steps after FIGS. 14A and 14B, respectively.

FIGS. 16A and 16B are diagrams illustrating steps after FIGS. 15A and 15B, respectively.

FIGS. 17A and 17B are diagrams illustrating steps after FIGS. 16A and 16B, respectively.

FIG. 18 is a schematic cross-sectional view illustrating a partial region of a semiconductor device according to a second preferred embodiment of the present disclosure.

FIG. 19 is a schematic cross-sectional view illustrating a partial region of the semiconductor device according to the second preferred embodiment of the present disclosure.

FIG. 20 is a schematic cross-sectional view illustrating a partial region of the semiconductor device according to the second preferred embodiment of the present disclosure.

FIG. 21 is a schematic cross-sectional perspective view illustrating a partial region of a semiconductor device according to a third preferred embodiment of the present disclosure.

FIG. 22 is a schematic cross-sectional perspective view illustrating a partial region of a semiconductor device according to a fourth preferred embodiment of the present disclosure.

FIG. 23 is a diagram illustrating steps associated with the formation of the structure in FIG. 22.

### DESCRIPTION OF EMBODIMENTS

Next, preferred embodiments of the present disclosure shall be described in detail with reference to the attached drawings.

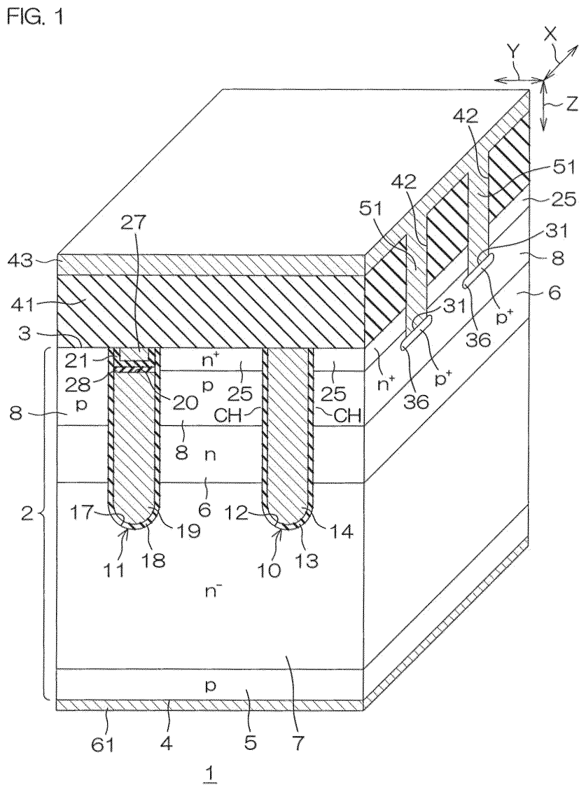

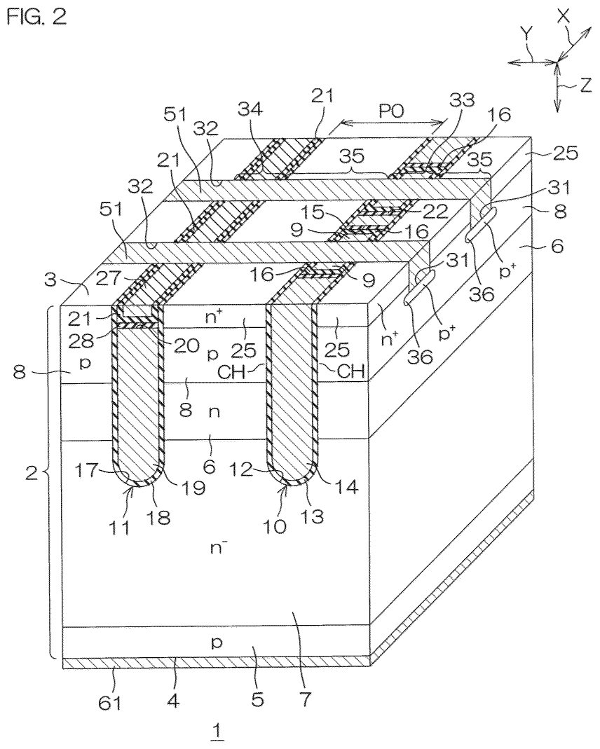

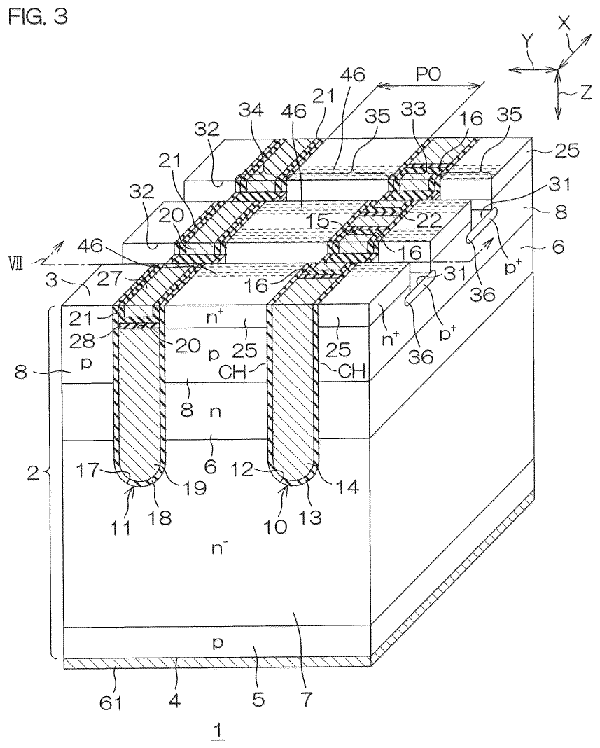

FIG. 1 is a schematic cross-sectional perspective view illustrating a partial region of a semiconductor device 1 according to a first preferred embodiment of the present disclosure. FIG. 2 is a diagram in which the structure on a first principal surface 3 of a chip 2 is removed from FIG. 1. FIG. 3 is a view in which an emitter contact electrode layer 51 is removed from FIG. 2.

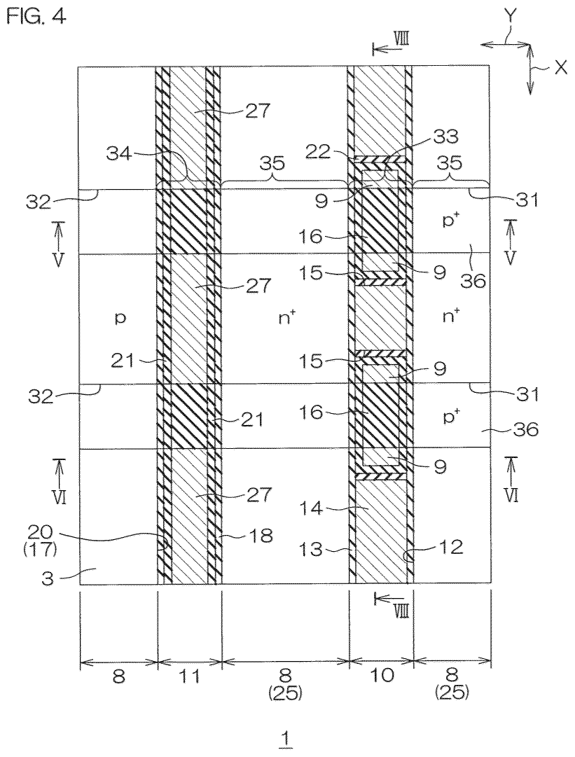

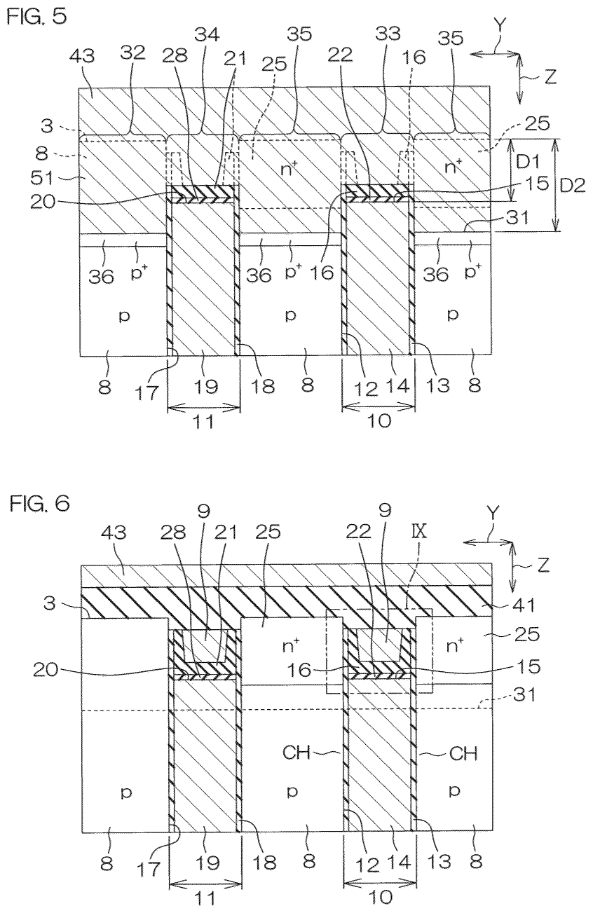

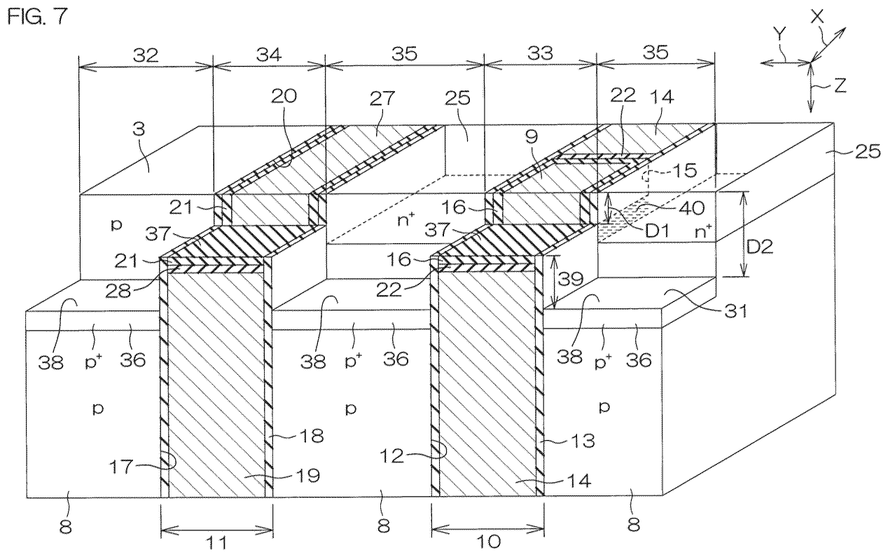

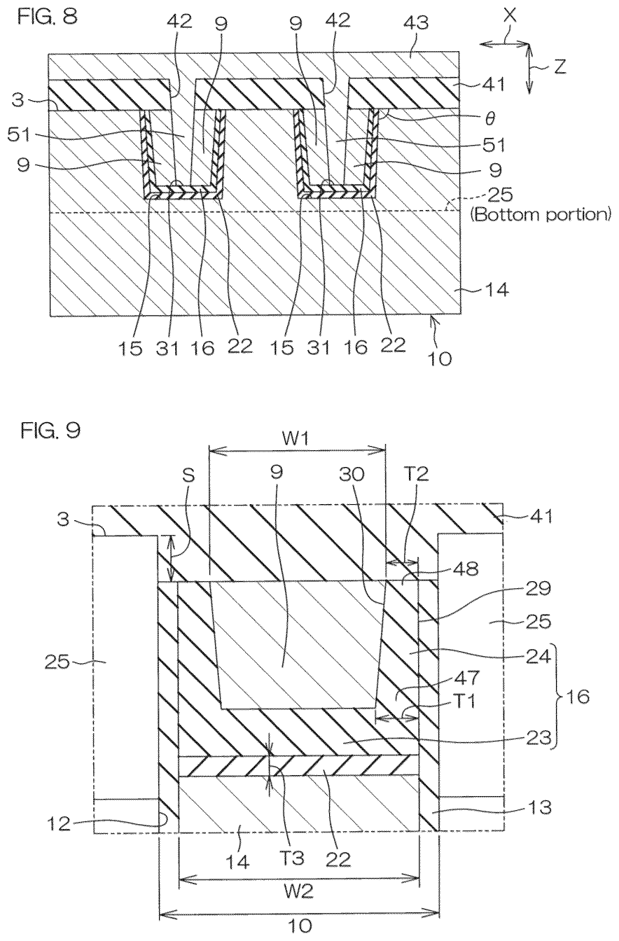

FIG. 4 is a schematic plan view of FIG. 3 as viewed from the first principal surface 3 of the chip 2. FIG. 5 is a cross-sectional view taken along line V-V illustrated in FIG. 4. FIG. 6 is a cross-sectional view taken along line VI-VI illustrated in FIG. 4. FIG. 7 is a cross-sectional perspective view taken along VII-VII illustrated in FIG. 3. FIG. 8 is a cross-sectional view taken along line VIII-VIII illustrated in FIG. 4. FIG. 9 is an enlarged view of a portion surrounded by an alternate long and two short dashed line IX in FIG. 6. FIGS. 5, 6, and 8 also illustrate the structure on the first principal surface 3 of the chip 2.

In this preferred embodiment, the semiconductor device 1 has a basic form including a trench-gate type IGBT (Insulated Gate Bipolar Transistor). Referring to FIGS. 1 to 3, the semiconductor device 1 includes the chip 2 of an n″-type. In this preferred embodiment, the chip 2 is constituted of a silicon monocrystal substrate of the n-type. The silicon monocrystal substrate is formed by using a semiconductor wafer of the n-type silicon monocrystal manufactured through an FZ (Floating Zone) method. The chip 2 may be referred to as a semiconductor chip or a semiconductor layer.

The chip 2 has the first principal surface 3 on one side and a second principal surface 4 on the other side. A thickness of the chip 2 may be 50 μm or more and 300 μm or less. The thickness of the chip 2 may be 50 μm or more and 100 μm or less, 100 μm or more and 150 μm or less, 150 μm or more and 200 μm or less, 200 μm or more and 250 μm or less, or 250 μm or more and 300 μm or less.

Referring to FIGS. 1 to 3, a collector region 5 of a p-type is formed in a surface portion of the second principal surface 4. A charge storage region 6 of an n-type is formed in a surface portion of the first principal surface 3. The charge storage region 6 is formed on the first principal surface 3 side with an interval from the collector region 5.

Referring to FIGS. 1 to 3, a drift region 7 of the n″-type is formed in a region between the collector region 5 and the charge storage region 6 in the chip 2. The drift region 7 is formed by a region positioned between the collector region 5 and the charge storage region 6 in the chip 2. A body region 8 of the p-type is formed in a surface portion of the charge storage region 6. A plurality of trench gate electrode structures 10 and a plurality of trench emitter electrode structures 11 are formed in the surface portion of the first principal surface 3 at intervals.

Only the single trench gate electrode structure 10 and the single trench emitter electrode structure 11 that are adjacent to each other are shown in FIGS. 1 to 7. A structure of the semiconductor device I will be hereinafter described while paying attention to the structure of the single trench gate electrode structure 10 and that of the single trench emitter electrode structure 11.

The trench gate electrode structure 10 and the trench emitter electrode structure 11 extend as a band along an arbitrary first direction X in plan view. The trench gate electrode structure 10 and the trench emitter electrode structure 11 are formed at an interval along a second direction Y intersecting the first direction X.

More specifically, the term “plan view” denotes a plan view seen from a normal direction Z to the first principal surface 3 (hereinafter, referred to simply as “normal direction Z”). More specifically, the second direction Y is a direction perpendicular to the first direction X. The first direction X and the second direction Y are each also a tangential direction to the first principal surface 3.

A trench pitch P0 between the trench gate electrode structure 10 and the trench emitter electrode structure 11 may be 0.1 μm or more and less than 0.6 μm. The trench pitch P0 may be 0.1 μm or more and 0.2 μm or less, 0.2 μm or more and 0.3 μm or less, 0.3 μm or more and 0.4 μm or less, 0.4 μm or more and 0.5 μm or less, or 0.5 μm or more and less than 0.6 μm. The trench pitch P0 is preferably 0.2 μm or more and 0.4 μm or less (for example, about 0.25 μm).

The trench gate electrode structure 10 includes a gate trench 12, a gate insulating layer 13, a gate electrode layer 14, a plurality of gate electrode recess portions 15, a plurality of gate covering insulating layers 16, a plurality of gate embedded bodies 9, and a plurality of gate intermediate insulating layers 22. The gate trench 12 passes through the body region 8 and the charge storage region 6 from the first principal surface 3 and reaches the drift region 7.

A depth of the gate trench 12 may be 2.0 μm or more and 4.0 μm or less. The depth of the gate trench 12 may be 2.0 μm or more and 2.5 μm or less, 2.5 μm or more and 3.0 μm or less, 3.0 μm or more and 3.5 μm or less, or 3.5 μm or more and 4.0 μm or less. The depth of the gate trench 12 is preferably 2.5 μm or more and 3.5 μm or less (for example, about 3.0 μm).

A second-direction width of the gate trench 12 may be 0.5 μm or more and 1.5 μm or less. The second-direction width of the gate trench 12 may be 0.5 μm or more and 0.75 μm or less, 0.75 μm or more and 1.0 μm or less, 1.0 μm or more and 1.25 μm or less, or 1.25 μm or more and 1.5 μm or less. The second-direction width of the gate trench 12 is preferably 0.5 μm or more and 1.0 μm or less (for example, about 0.75 μm).

The gate insulating layer 13 may be formed of silicon oxide. The gate insulating layer 13 is formed as a film along an inner wall of the gate trench 12. The gate insulating layer 13 defines a recessed space in the gate trench 12.

The gate electrode layer 14 may be formed of conductive polysilicon. The gate electrode layer 14 is controlled by a gate voltage. The gate electrode layer 14 is embedded in the gate trench 12 across the gate insulating layer 13. More specifically, the gate electrode layer 14 is embedded in the recessed space defined by the gate insulating layer 13 in the gate trench 12.

In this preferred embodiment, the plurality of gate electrode recess portions 15 are formed in an upper surface of the gate electrode layer 14 at intervals along the first direction X. As a result, an upper end portion of the gate electrode layer 14 has an uneven structure including the plurality of gate electrode recess portions 15.

An interval between the plurality of gate electrode recess portions 15 adjacent to each other may be more than 0 μm and 10 μm or less. The interval between the plurality of gate electrode recess portions 15 adjacent to each other is also a width in the first direction X of a part sandwiched between the two gate electrode recess portions 15 adjacent to each other in the gate electrode layer 14. The interval between the plurality of gate electrode recess portions 15 adjacent to each other may be more than 0 μm and 2 μm or less, 2 μm or more and 4 μm or less, 4 μm or more and 6 μm or less, 6 μm or more and 8 μm or less, or 8 μm or more and 10 μm or less.

In this preferred embodiment, side walls of each gate electrode recess portion 15 are formed by the gate insulating layer 13 and the gate electrode layer 14. A pair of side walls facing each other in the first direction X are formed by the gate electrode layer 14, and a pair of side walls facing each other in the second direction Y are formed by the gate insulating layer 13. A bottom wall of each gate electrode recess portion 15 is formed by the gate electrode layer 14. Referring to FIG. 8, the bottom wall of each gate electrode recess portion 15 may be positioned in a region between the first principal surface 3 and a bottom portion of an emitter region 25 (described later) in the normal direction Z or may be positioned in a portion deeper than the bottom portion of the emitter region 25.

Referring to FIG. 8, each gate electrode recess portion 15 is formed in a tapered shape having a bottom area smaller than an opening area. An angle θ formed by the upper surface of the gate electrode layer 14 and the side wall of the gate electrode recess portion 15 in the gate electrode layer 14 may be more than 90° and 120° or less (for example, about 102°).

The plurality of gate covering insulating layers 16 are formed on the upper surface of the gate electrode layer 14 and the side wall of the gate electrode recess portion 15 in the gate trench 12. More specifically, the plurality of gate covering insulating layers 16 are respectively independently formed in the plurality of gate electrode recess portions 15. Each gate covering insulating layer 16 covers the gate electrode layer 14 in the gate trench 12, is formed along the side wall of the gate electrode recess portion 15, and is exposed from an opening of the gate trench 12. Each gate covering insulating layer 16 defines a recessed space in each gate electrode recess portion 15. The recessed space in the gate electrode recess portion 15 is surrounded by the gate covering insulating layer 16 from below and lateral sides.

Referring to FIG. 9, the gate covering insulating layer 16 includes a bottom portion 23 covering the upper surface of the gate electrode layer 14 and a side portion 24 extending upward from the bottom portion 23 along a side wall of the gate trench 12. The bottom portion 23 of the gate covering insulating layer 16 has a thickness of 150 nm or more and 300 nm or less. On the other hand, the side portion 24 of the gate covering insulating layer 16 has a first thickness T1 at a lower end portion 47 in a depth direction of the gate trench 12 and has a second thickness T2 thinner than the first thickness T1 at an upper end portion 48 in the depth direction of the gate trench 12. The first thickness T1 is, for example, 300 nm or less, and the second thickness T2 is, for example, 50 nm or less. Also, a width W1 of an upper end portion of the gate embedded body 9 may be narrower than a width W2 of the upper end portion of the gate electrode layer 14.

The side portion 24 of the gate covering insulating layer 16 has a tapered shape in which an outer side surface 29 on the side close to the side wall of the gate trench 12 and an inner side surface 30 on the opposite side of the outer side surface 29 are inclined such as to approach each other from the lower end portion 47 toward the upper end portion 48 of the gate covering insulating layer 16 in cross-sectional view. A level difference S may be formed between an upper end of the side portion 24 of the gate covering insulating layer 16 and the first principal surface 3. In other words, the upper end of the side portion 24 of the gate covering insulating layer 16 may be disposed at a height position lower than the first principal surface 3 in the depth direction of the gate trench 12.

In this preferred embodiment, the plurality of gate embedded bodies 9 may be formed of the same material as the gate electrode layer 14. That is, the plurality of gate embedded bodies 9 may be formed of conductive polysilicon. The gate embedded body 9 has conductivity, but in this preferred embodiment, may be electrically floating. The gate embedded body 9 is embedded in the gate electrode recess portion 15 across the gate covering insulating layer 16. More specifically, the gate embedded body 9 is embedded in a recessed space defined by the gate covering insulating layer 16 in the gate electrode recess portion 15.

The plurality of gate intermediate insulating layers 22 may be formed of silicon oxide. Each gate intermediate insulating layer 22 is interposed between the gate electrode layer 14 and the gate covering insulating layer 16 in each gate electrode recess portion 15. Referring to FIG. 9, in this preferred embodiment, the gate intermediate insulating layer 22 is formed between the upper surface of the gate electrode layer 14 and the bottom portion 23 of the gate covering insulating layer 16. The thickness (a third thickness T3) of the gate intermediate insulating layer 22 may be, for example, 20 nm or more and 150 nm or less. The gate intermediate insulating layer 22 is clearly distinguished from the gate covering insulating layer 16 (the bottom portion 23) in FIG. 9. Depending on the conditions of the manufacturing process, the gate intermediate insulating layer 22 may not be distinguished from the gate covering insulating layer 16 and may be integrated with the gate covering insulating layer 16 in appearance.

The trench emitter electrode structure 11 includes an emitter trench 17, an emitter insulating layer 18, an emitter electrode layer 19, an emitter electrode recess portion 20, an emitter covering insulating layer 21, an emitter embedded body 27, and an emitter intermediate insulating layer 28. The emitter trench 17 penetrates the body region 8 and the charge storage region 6 from the first principal surface 3 and reaches the drift region 7.

A depth of the emitter trench 17 may be 2.0 μm or more and 4.0 μm or less. The depth of the emitter trench 17 may be 2.0 μm or more and 2.5 μm or less, 2.5 μm or more and 3.0 μm or less, 3.0 μm or more and 3.5 μm or less, or 3.5 μm or more and 4.0 μm or less. The depth of the emitter trench 17 is preferably 2.5 μm or more and 3.5 μm or less (for example, about 3.0 μm). Preferably, the depth of the emitter trench 17 is substantially equal to the depth of the gate trench 12.

A second-direction width of the emitter trench 17 may be 0.5 μm or more and 1.5 μm or less. The second-direction width of the emitter trench 17 may be 0.5 μm or more and 0.75 μm or less, 0.75 μm or more and 1.0 μm or less, 1.0 μm or more and 1.25 μm or less, or 1.25 μm or more and 1.5 μm or less. The second-direction width of the emitter trench 17 is preferably 0.5 μm or more and 1.0 μm or less (for example, about 0.75 μm). Preferably, the second-direction width of the emitter trench 17 is substantially equal to the second-direction width of the gate trench 12.

The emitter insulating layer 18 may be formed of silicon oxide. The emitter insulating layer 18 is formed as a film along an inner wall of the emitter trench 17. The emitter insulating layer 18 defines a recessed space in the emitter trench 17.

The emitter electrode layer 19 may be formed of conductive polysilicon. The emitter electrode layer 19 is controlled by an emitter voltage. The emitter voltage has a voltage value less than a gate voltage. The emitter voltage may be a reference voltage (for example, ground voltage). The emitter electrode layer 19 is embedded in the emitter trench 17 across the emitter insulating layer 18. More specifically, the emitter electrode layer 19 is embedded in the recessed space defined by the emitter insulating layer 18 in the emitter trench 17.

In this preferred embodiment, the emitter electrode recess portion 20 is formed such as to dig down substantially the entirety of an upper surface of the emitter electrode layer 19. In other words, the emitter electrode layer 19 is embedded to a halfway portion in the depth direction of the recessed space defined by the emitter insulating layer 18.

In this preferred embodiment, side walls of the emitter electrode recess portion 20 are formed by the emitter insulating layer 18. A bottom wall of the emitter electrode recess portion 20 is formed by the emitter electrode layer 19. Referring to FIGS. 5 and 6, the bottom wall of the emitter electrode recess portion 20 may be positioned in the region between the first principal surface 3 and the bottom portion of the emitter region 25 (described later) in the normal direction Z or may be positioned in a portion deeper than the bottom portion of the emitter region 25. That is, an upper end portion of the emitter electrode layer 19 is positioned on the first principal surface 3 side with respect to the bottom portion of the emitter region 25 (described later). In the normal direction Z, a depth of the emitter electrode recess portion 20 may be approximately equal to a depth of the gate electrode recess portion 15.

The emitter covering insulating layer 21 is formed on the upper surface of the emitter electrode layer 19 and the side walls of the emitter electrode recess portion 20 in the emitter trench 17. That is, the emitter covering insulating layer 21 is formed along an inner wall of the emitter electrode recess portion 20. The emitter covering insulating layer 21 covers the emitter electrode layer 19 in the emitter trench 17, is formed along the side walls of the emitter electrode recess portion 20, and is exposed from an opening of the emitter trench 17. The emitter covering insulating layer 21 defines a recessed space in the emitter electrode recess portion 20. The recessed space in the emitter electrode recess portion 20 is surrounded by the emitter covering insulating layer 21 from below and lateral sides. Although description is omitted, the emitter covering insulating layer 21 has the same cross-sectional shape as the gate covering insulating layer 16 illustrated in FIG. 9.

In this preferred embodiment, the emitter embedded body 27 may be formed of the same material as the emitter electrode layer 19. That is, the emitter embedded body 27 may be formed of conductive polysilicon. The emitter embedded body 27 has conductivity, but in this preferred embodiment, may be electrically floating. The emitter embedded body 27 is embedded in the emitter electrode recess portion 20 across the emitter covering insulating layer 21. More specifically, the emitter embedded body 27 is embedded in a recessed space defined by the emitter covering insulating layer 21 in the emitter electrode recess portion 20.

The emitter intermediate insulating layer 28 may be formed of silicon oxide. The emitter intermediate insulating layer 28 is interposed between the emitter electrode layer 19 and the emitter covering insulating layer 21 in the emitter electrode recess portion 20.

The emitter region 25 (impurity region) of an n⁺-type is formed in a region along the side wall of the gate trench 12 in a surface portion of the body region 8. More specifically, a plurality of the emitter regions 25 are formed, in the first direction X, along a side wall on one side and along a side wall on the other side of the gate trench 12. The plurality of emitter regions 25 are each formed as a band extending along the first direction X. The emitter region 25 is in contact with the side wall of the gate trench 12. The emitter region 25 is in contact also with a side wall of the emitter trench 17.

The emitter region 25, the body region 8, the charge storage region 6, and the drift region 7 are formed in that order from the first principal surface 3 toward the second principal surface 4 side in the region along the side wall of the gate trench 12 in the surface portion of the first principal surface 3. In the body region 8, a channel CH of the IGBT is formed in a region facing the gate electrode layer 14 across the gate insulating layer 13.

Referring to FIGS. 3 to 6 and FIG. 7, a plurality of contact trenches 31 are formed in the surface portion of the first principal surface 3. The plurality of contact trenches 31 are formed at intervals along the first direction X. Each of the plurality of contact trenches 31 is formed as a band extending along the second direction Y. A first-direction width of each contact trench 31 is smaller than the second-direction width of the gate trench 12.

More specifically, each contact trench 31 penetrates the side walls of the gate trench 12 from an inner region of the corresponding gate covering insulating layer 16 and is led out to the surface portion of the first principal surface 3. In this preferred embodiment, each contact trench 31 penetrates the side wall on one side and the side wall on the other side of the gate trench 12 from the inner region of the gate covering insulating layer 16 in the second direction Y.

Each contact trench 31 includes a first intersection region 33 intersecting the gate electrode layer 14 in plan view. In the first intersection region 33, a bottom wall of each contact trench 31 is formed by the gate covering insulating layer 16, and side walls of each contact trench 31 are formed by the gate embedded body 9.

Each contact trench 31 includes a second intersection region 34 intersecting the emitter electrode layer 19 in plan view. In the second intersection region 34, the bottom wall of each contact trench 31 is formed by the emitter covering insulating layer 21, and the side walls of each contact trench 31 are formed by the emitter embedded body 27.

Each contact trench 31 further includes a contact region 35 led out from the first intersection region 33 to the outside of the gate trench 12. The contact region 35 may be referred to as a connection region that connects the first intersection region 33 and the second intersection region 34 in a region between the gate trench 12 and the emitter trench 17 in plan view. In the contact region 35, the bottom wall of each contact trench 31 is formed by the body region 8, and the side walls of each contact trench 31 are formed by the body region 8 and the emitter region 25. That is, the laminated structure of the body region 8 and the emitter region 25 is exposed on the side wall of the contact trench 31 in the contact region 35.

Each contact trench 31 further includes a lead-out portion 32 led out from the side wall on one side of the emitter trench 17 to the outside. Each lead-out portion 32 penetrates the side wall on one side of the emitter trench 17 from the surface portion of the first principal surface 3 and reaches the inside of the emitter trench 17.

Referring to FIG. 7, a first depth D1 from the first principal surface 3 to the upper surface of the gate electrode layer 14 in the first intersection region 33 is shallower than a second depth D2 of the contact trench 31 in the contact region 35. Therefore, the contact trench 31 has an uneven structure in which the gate electrode layer 14 and the emitter electrode layer 19 selectively project in the second direction Y. For example, the first depth D1 is 1 μm or less, preferably 0.5 μm or more and 1 μm or less. The second depth D2 is 0.3 μm or more and 1.0 μm or less.

In the first intersection region 33, the upper end portion of the gate electrode layer 14 is positioned on the first principal surface 3 side with respect to the bottom portion of the emitter region 25. As a result, the gate electrode layer 14 has a facing portion 40 facing the emitter region 25 via the gate insulating layer 13 near both sides of the first intersection region 33 in the first direction X. The facing portion 40 is a region indicated by lateral hatching in FIG. 7. The facing portion 40 is positioned below a pair of the gate embedded bodies 9 in the normal direction Z.

The contact trench 31 includes a first bottom wall 37 in the first intersection region 33 and the second intersection region 34 and a second bottom wall 38 in the contact region 35 and the lead-out portion 32. A level difference 39 resulting from the difference between the first depth D1 and the second depth D2 is formed between the first bottom wall 37 and the second bottom wall 38.

The plurality of contact trenches 31 are arbitrarily arranged. The plurality of contact trenches 31 may be formed at equal intervals along the first direction X. The plurality of contact trenches 31 may be formed at unequal intervals along the first direction X.

A contact region 36 of a p⁺-type is formed in a region along the bottom wall of each contact trench 31 in the body region 8. The contact region 36 may be formed in a region along the bottom wall and the side walls of each contact trench 31 in the body region 8. The contact region 36 is formed in a region that is deeper, in the normal direction Z, than the emitter region 25 in the body region 8.

The contact region 36 has an exposed surface exposed from the bottom wall of the contact trench 31. The exposed surface of the contact region 36 is formed in a region between the first principal surface 3 and a bottom portion of the body region 8. More specifically, the exposed surface of the contact region 36 is formed in a region between the bottom portion of the body region 8 and the bottom portion of the emitter region 25. More specifically, the exposed surface of the contact region 36 is formed below the upper surface of the gate electrode layer 14 and the upper surface of the emitter electrode layer 19.

An interlayer insulating layer 41 is formed on the first principal surface 3. The interlayer insulating layer 41 covers the trench gate electrode structure 10 and the trench emitter electrode structure 11. The interlayer insulating layer 41 covers the gate covering insulating layer 16 and the gate embedded body 9 exposed from the gate trench 12, and the emitter covering insulating layer 21 and the emitter embedded body 27 exposed from the emitter trench 17.

The interlayer insulating layer 41 may be formed of silicon oxide or silicon nitride. The interlayer insulating layer 41 may have a laminated structure including an oxide film (SiO₂ film) and a nitride film (SiN film). The oxide film (SiO₂ film) may include an NSG (Nondoped Silicon Glass) film that does not contain impurities and/or a PSG (Phosphorus Silicon Glass) film that contains phosphorus.

The interlayer insulating layer 41 may have a laminated structure including an NSG film and a PSG film laminated in that order from the first principal surface 3. A thickness of the NSG film may be 2000 Å or more and 8000 Å or less (for example, about 5000 Å). A thickness of the PSG film may be 2000 Å or more and 6000 Å or less (for example, about 4000 Å).

A plurality of contact holes 42 are formed in the interlayer insulating layer 41. Each of the plurality of contact holes 42 communicates with the corresponding contact trench 31. In other words, the plurality of contact holes 42 are formed at intervals along the first direction X and are each formed as a band extending along the second direction Y.

The plurality of contact holes 42 pass through the interlayer insulating layer 41 and communicate with the corresponding contact trenches 31, respectively. As a result, the plurality of contact holes 42 each form one emitter contact trench 31, 42 with the corresponding contact trench 31.

A first-direction width of each contact hole 42 may be equal to or larger than the first-direction width of each contact trench 31. That is, the first-direction width of each contact hole 42 may be equal to the first-direction width of each contact trench 31 or may exceed the first-direction width of each contact trench 31. When the first-direction width of each contact hole 42 exceeds the first-direction width of each contact trench 31, an inner wall of each contact hole 42 may surround an inner wall of the corresponding contact trench 31.

The arrangement of the plurality of contact holes 42 is arbitrary and is adjusted according to the arrangement of the contact trenches 31. The plurality of contact holes 42 may be formed at equal intervals along the first direction X. The plurality of contact holes 42 may be formed at unequal intervals along the first direction X.

An emitter principal surface electrode layer 43 is formed on the interlayer insulating layer 41. The emitter principal surface electrode layer 43 enters the contact hole 42 and the contact trench 31 (that is, the emitter contact trench 31, 42) from above the interlayer insulating layer 41. The emitter principal surface electrode layer 43 may include, for example, a laminated structure of a barrier layer of titanium or the like and an electrode layer of tungsten or the like. In this preferred embodiment, the plurality of emitter contact electrode layers 51 are formed by parts of the emitter principal surface electrode layer 43 positioned in the plurality of contact trenches 31. As a result, a structure in which the plurality of emitter contact electrode layers 51 are embedded in a surface portion of the chip 2 is formed.

Each of the plurality of emitter contact electrode layers 51 has an arrangement and a shape corresponding to the arrangement and the shape of the plurality of contact trenches 31. In other words, the plurality of emitter contact electrode layers 51 are formed at intervals along the first direction X and are each formed as a band extending along the second direction Y.

Each emitter contact electrode layer 51 faces the gate electrode layer 14 across the gate covering insulating layer 16 in the normal direction Z and the first direction X in the first intersection region 33 intersecting the gate electrode layer 14 in plan view. Each emitter contact electrode layer 51 is insulated from the gate electrode layer 14 by the gate covering insulating layer 16.

In the first intersection region 33, the gate embedded body 9 is interposed between the emitter contact electrode layer 51 and the gate covering insulating layer 16. In this preferred embodiment, in the first intersection region 33, the gate embedded bodies 9 include a pair of the gate embedded bodies 9 which are provided on both sides in the first direction X with respect to the first intersection region 33 and sandwich the emitter contact electrode layer 51 from both lateral sides in the first direction X. Therefore, in the first intersection region 33, the emitter contact electrode layer 51 is in direct contact with the gate covering insulating layer 16 in the normal direction Z and is in contact with the gate embedded bodies 9 in the first direction X. The emitter contact electrode layer 51 is surrounded from three directions, that is, by the gate covering insulating layer 16 below and the gate embedded bodies 9 on both lateral sides.

Each emitter contact electrode layer 51 faces the emitter electrode layer 19 across the emitter covering insulating layer 21 in the normal direction Z and the first direction X in the second intersection region 34 intersecting the emitter electrode layer 19 in plan view. Each emitter contact electrode layer 51 is insulated from the emitter electrode layer 19 by the emitter covering insulating layer 21.

In the second intersection region 34, the emitter embedded body 27 is interposed between the emitter contact electrode layer 51 and the emitter covering insulating layer 21. In this preferred embodiment, in the second intersection region 34, the emitter embedded bodies 27 include a pair of the emitter embedded bodies 27 which are provided on both sides in the first direction X with respect to the second intersection region 34 and sandwich the emitter contact electrode layer 51 from both lateral sides in the first direction X. Therefore, in the second intersection region 34, the emitter contact electrode layer 51 is in direct contact with the emitter covering insulating layer 21 in the normal direction Z and is in contact with the emitter embedded bodies 27 in the first direction X. The emitter contact electrode layer 51 is surrounded from three directions, that is, by the emitter covering insulating layer 21 below and the emitter embedded bodies 27 on both lateral sides.

A collector electrode layer 61 is formed on the second principal surface 4 of the chip 2. The collector electrode layer 61 is connected to the collector region 5. Although not illustrated, a gate principal surface electrode layer that has the same structure as the emitter principal surface electrode layer 43 may be formed on the interlayer insulating layer 41. The gate principal surface electrode layer may be electrically connected to the gate electrode layer 14 through a gate contact hole formed in the interlayer insulating layer 41.

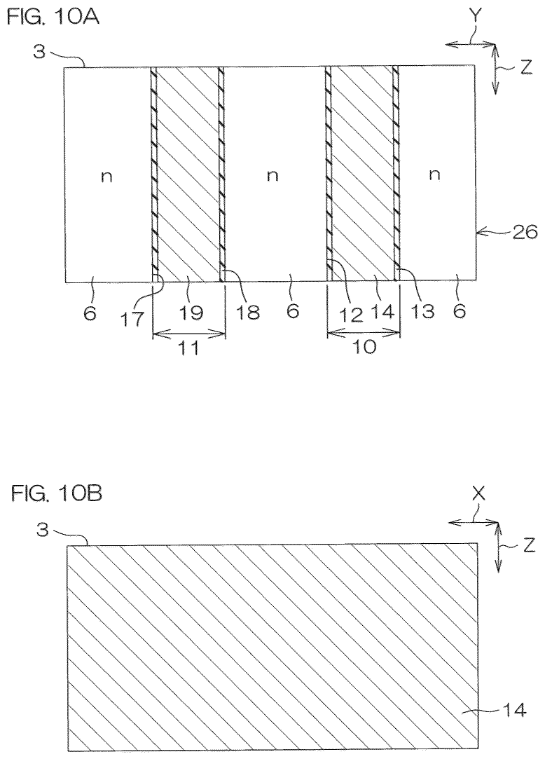

FIGS. 10A and 10B to FIGS. 17A and 17B are diagrams illustrating part of the manufacturing process of the semiconductor device 1 in the order of steps. In FIGS. 10A and 10B to FIGS. 17A and 17B, the figure with each figure number suffixed with “A” corresponds to the cross section of FIG. 5, and the figure with the figure number suffixed with “B” corresponds to the cross section of FIG. 8.

Referring to FIGS. 10A and 10B, first, an n-type semiconductor wafer 26 is prepared. The semiconductor wafer 26 has the first principal surface 3 and the second principal surface 4 (not illustrated) of the chip 2 described above. Next, the p-type collector region 5 (not illustrated) and the n-type charge storage region 6 are formed in the semiconductor wafer 26. The collector region 5 is formed by introducing a p-type impurity into the second principal surface 4 of the semiconductor wafer 26. The collector region 5 may be formed in the surface portion of the second principal surface 4 of the semiconductor wafer 26 by an ion implantation method through an ion implantation mask (not shown). The charge storage region 6 is formed by introducing an n-type impurity into the first principal surface 3. The charge storage region 6 may be formed in the surface portion of the first principal surface 3 by the ion implantation method through an ion implantation mask (not shown).

Next, unnecessary portions of the semiconductor wafer 26 are selectively removed from the first principal surface 3 via a mask having a predetermined pattern. The unnecessary portions of the semiconductor wafer 26 may be removed by an etching method (for example, a wet etching method). Accordingly, the gate trench 12 and the emitter trench 17 are formed. Thereafter, the mask is removed. Next, the gate insulating layer 13 and the emitter insulating layer 18 are formed on the inner wall of the gate trench 12 and the inner wall of the emitter trench 17, respectively, by, for example, a thermal oxidation treatment method or a wet oxidation treatment method. Next, the gate electrode layer 14 and the emitter electrode layer 19 are embedded in the gate trench 12 and the emitter trench 17, respectively, for example, by a CVD method. As a result, the trench gate electrode structure 10 and the trench emitter electrode structure 11 are formed.

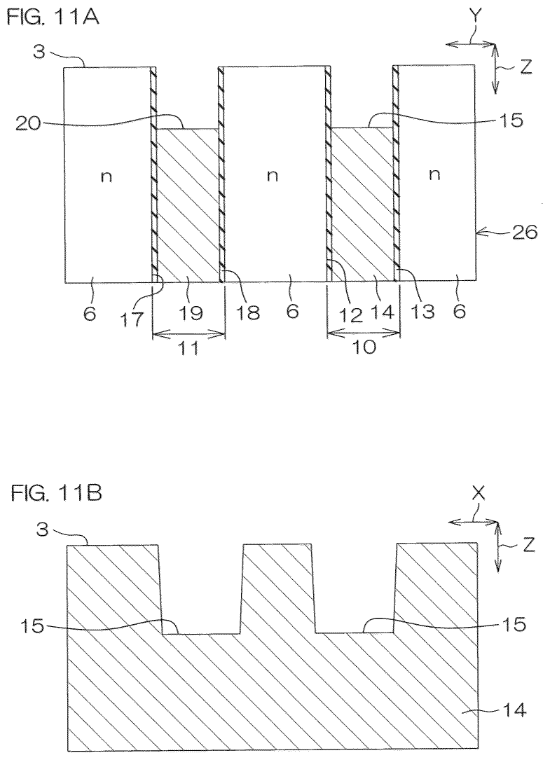

Next, referring to FIGS. 11A and 11B, unnecessary portions of the gate electrode layer 14 and the emitter electrode layer 19 are selectively removed from the first principal surface 3 via a mask having a predetermined pattern. Thus, the gate electrode recess portion 15 and the emitter electrode recess portion 20 are formed. The unnecessary portions of the gate electrode layer 14 and the unnecessary portions of the emitter electrode layer 19 may be removed by an etching method (for example, a wet etching method).

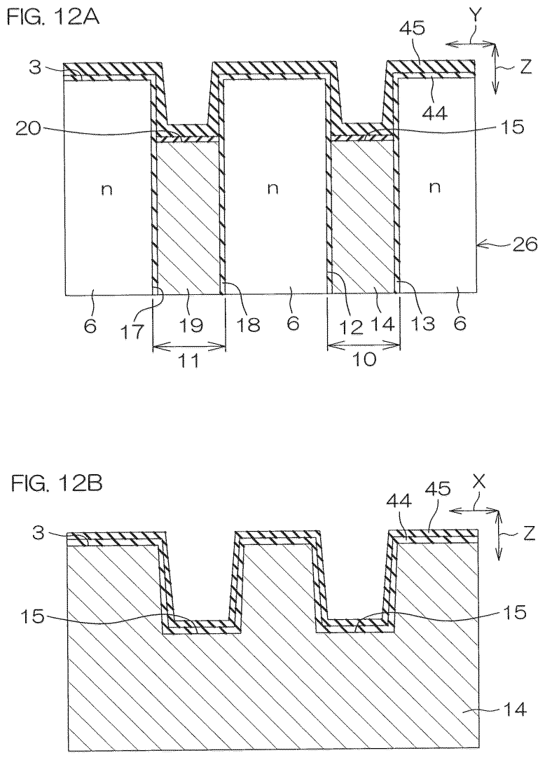

Next, referring to FIGS. 12A and 12B, a first base insulating layer 44 that is to be a base of the gate intermediate insulating layer 22 and the emitter intermediate insulating layer 28, and a second base insulating layer 45 that is to be a base of the gate covering insulating layer 16 and the emitter covering insulating layer 21 are formed. The first base insulating layer 44 may be formed, for example, by thermal oxidation treatment on surfaces of the gate electrode layer 14 and the emitter electrode layer 19 and a surface of the semiconductor wafer 26. On the other hand, the second base insulating layer 45 may be formed by depositing an insulating material on the first base insulating layer 44 by, for example, a CVD method. The first base insulating layer 44 and the second base insulating layer 45 are formed in the gate trench 12 and the emitter trench 17 and are formed such as to cover the first principal surface 3 of the semiconductor wafer 26.

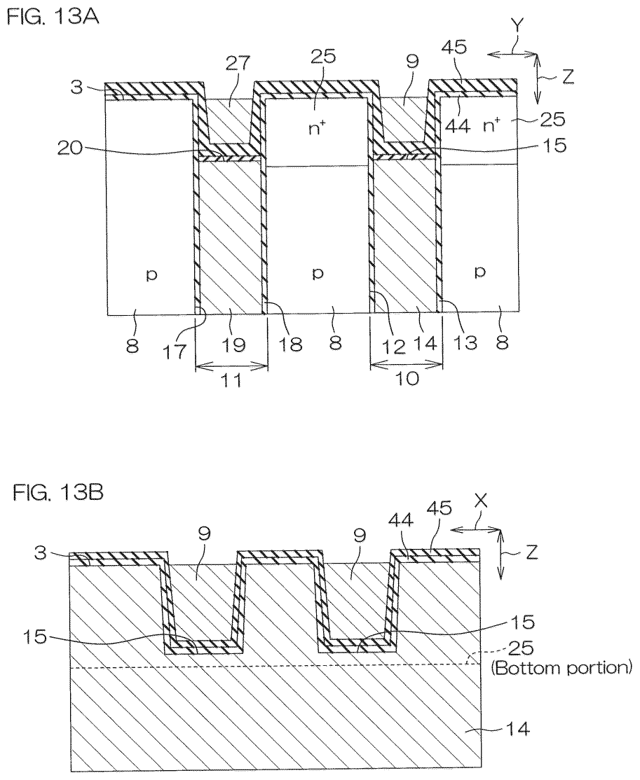

Next, referring to FIGS. 13A and 13B, a polysilicon layer that is to be a base of the gate embedded body 9 and the emitter embedded body 27 is deposited on an entire surface of the first principal surface 3 by, for example, a CVD method. Thereafter, by flattening the polysilicon layer by etching back, the gate embedded body 9 and the emitter embedded body 27 embedded in the gate electrode recess portion 15 and the emitter electrode recess portion 20, respectively, are obtained.

Next, the p-type body region 8 and the n⁺-type emitter region 25 are formed in the semiconductor wafer 26. The body region 8 is formed by introducing a p-type impurity into the first principal surface 3. The body region 8 may be formed in the surface portion of the first principal surface 3 by the ion implantation method through an ion implantation mask (not shown). The emitter region 25 is formed by introducing an n-type impurity into the first principal surface 3. The emitter region 25 may be formed in the surface portion of the first principal surface 3 by the ion implantation method through an ion implantation mask (not shown).

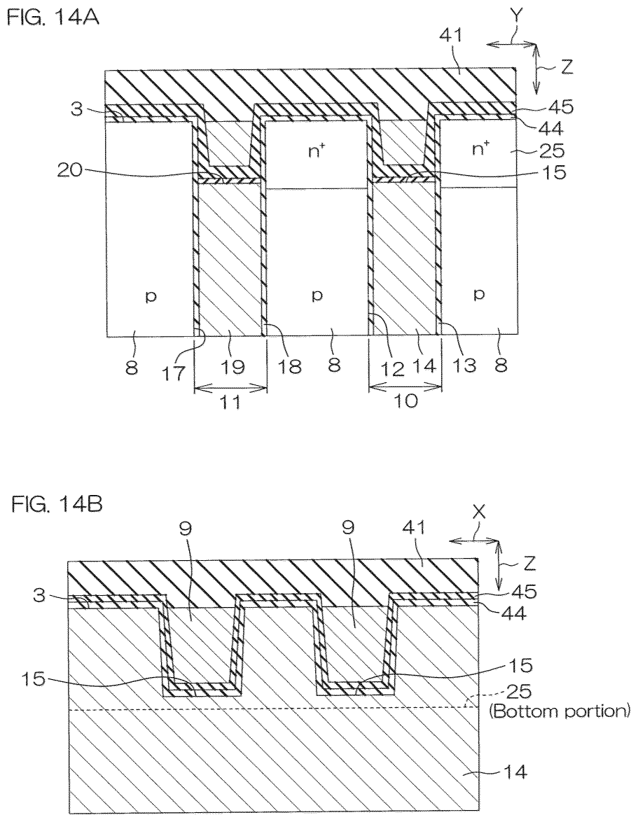

Next, referring to FIGS. 14A and 14B, the interlayer insulating layer 41 is formed on the first principal surface 3. The interlayer insulating layer 41 is formed on the first principal surface 3 such as to cover the trench gate electrode structure 10 and the trench emitter electrode structure 11. This step may include a step of forming an NSG film (for example, 5000 Å) and a PSG film (for example, 4000 Å) in that order on the first principal surface 3 by a CVD method.

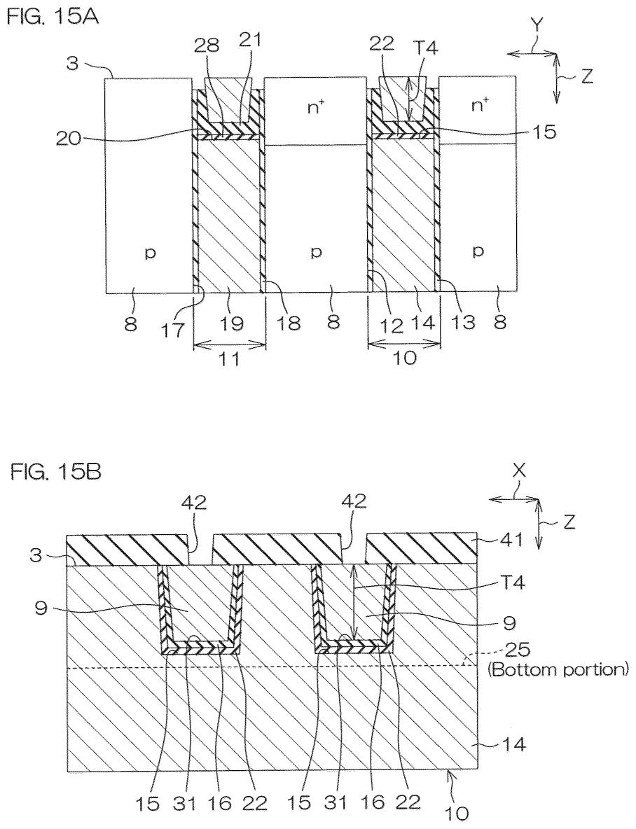

Next, referring to FIGS. 15A and 15B, unnecessary portions of the interlayer insulating layer 41, unnecessary portions of the gate covering insulating layer 16, and unnecessary portions of the emitter covering insulating layer 21 are selectively removed via a mask having a predetermined pattern. The unnecessary portions of the interlayer insulating layer 41, etc., may be removed by an etching method (for example, a dry etching method). Thus, the contact hole 42 is formed.

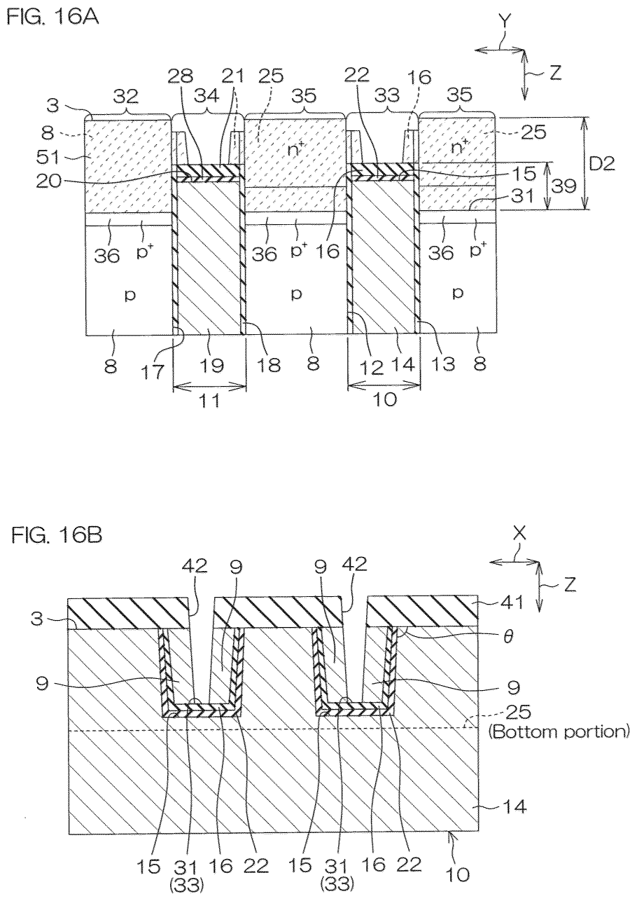

Next, referring to FIGS. 16A and 16B, unnecessary portions of the semiconductor wafer 26 are removed via the mask used at the time of forming the contact hole 42. The unnecessary portions of the semiconductor wafer 26 may be removed by, for example, an etching method (for example, a dry etching method). Thus, the contact trench 31 is formed on the first principal surface 3. Referring to FIG. 16A, the structure seen on the back side of the contact trench 31 is indicated by the broken line hatching.

In this preferred embodiment, since the semiconductor wafer 26 is a silicon monocrystal substrate and the gate embedded body 9 is polysilicon, the gate embedded body 9 is also etched at the same time when the contact trench 31 is formed. Also, the second depth D2 of the contact trench 31 is larger than a thickness T4 (see FIGS. 15A and 15B) of the gate embedded body 9. Therefore, in the first intersection region 33, the gate embedded body 9 is etched such that the gate embedded body 9 penetrates from the first principal surface 3 to the bottom wall of the gate electrode recess portion 15.

Next, the contact region 36 is formed in the surface portion of the first principal surface 3. More specifically, the contact region 36 is formed in a region along the bottom wall of the contact trench 31 in a surface layer portion of the body region 8. The contact region 36 may be formed in a region along the side wall and the bottom wall of the contact trench 31. The contact region 36 is formed by introducing a p-type impurity into the contact trench 31. The contact region 36 may be introduced into the contact trench 31 by the ion implantation method through an ion implantation mask (not shown). As a result, the contact region 36 along the bottom wall of the contact trench 31 is formed.

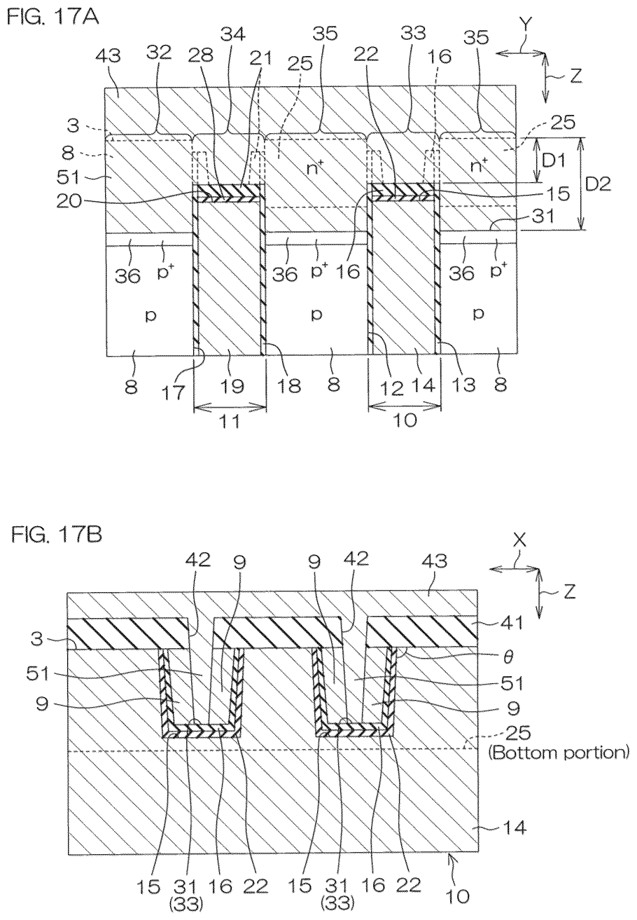

Next, referring to FIGS. 17A and 17B, the emitter principal surface electrode layer 43 is formed on the interlayer insulating layer 41. The emitter principal surface electrode layer 43 may be formed by a sputtering method or a CVD method. Then, the emitter contact electrode layer 51 is formed by the portion of the emitter principal surface electrode layer 43 that enters the contact trench 31. Also, the collector electrode layer 61 is formed on the second principal surface 4 of the semiconductor wafer 26. The semiconductor device 1 is obtained through the steps including the above steps.

As described above, according to the semiconductor device 1, the gate embedded body 9 is formed of polysilicon and has an etching selectivity to the interlayer insulating layer 41 constituted of silicon oxide or silicon nitride. That the gate embedded body 9 has an etching selectivity to the interlayer insulating layer 41 means that, for example, an etching selectivity (a/b) represented by the ratio of an etching amount (a) of the interlayer insulating layer 41 to an etching amount (b) of the gate embedded body 9 is 1.5 or more, preferably 5 or more, and more preferably 10 or more.

As a result, the gate embedded body 9 can be used as an etching stopper when the contact hole 42 is formed in the interlayer insulating layer 41 (see FIGS. 15A and 15B). The gate intermediate insulating layer 22 can be prevented from being exposed to the etching gas when the contact hole 42 is formed. Therefore, the thickness of the gate intermediate insulating layer 22 can be easily controlled to a design value by formation conditions of the gate intermediate insulating layer 22 (for example, thermal oxidation conditions, CVD conditions, and the like). Therefore, it is possible to prevent a short circuit between the gate electrode layer 14 and the emitter contact electrode layer 51 and a decrease in TZDB (Time Zero Dielectric Breakdown) and to improve the controllability of capacitance between the gate electrode layer 14 and the emitter contact electrode layer 51.

Also, the gate intermediate insulating layer 22 is not etched when the contact hole 42 is formed. Therefore, it is not necessary to form the gate intermediate insulating layer 22 excessively thick for the purpose of preventing a short circuit between the gate and the emitter due to over-etching of the gate intermediate insulating layer 22. Furthermore, it is not necessary to form the gate electrode recess portion 15 deep in order to form the thick gate intermediate insulating layer 22. As a result, since the gate electrode recess portion 15 can be formed relatively shallow, the facing portion 40 of the gate electrode layer 14 facing the emitter region 25 via the gate insulating layer 13 can be secured near both sides of the first intersection region 33. As a result, since a region near the first intersection region 33 can be used as a channel forming region 46 (see FIG. 3), reduction in channel width can be suppressed. Therefore, it is possible to provide the semiconductor device 1 capable of reducing the on-resistance.

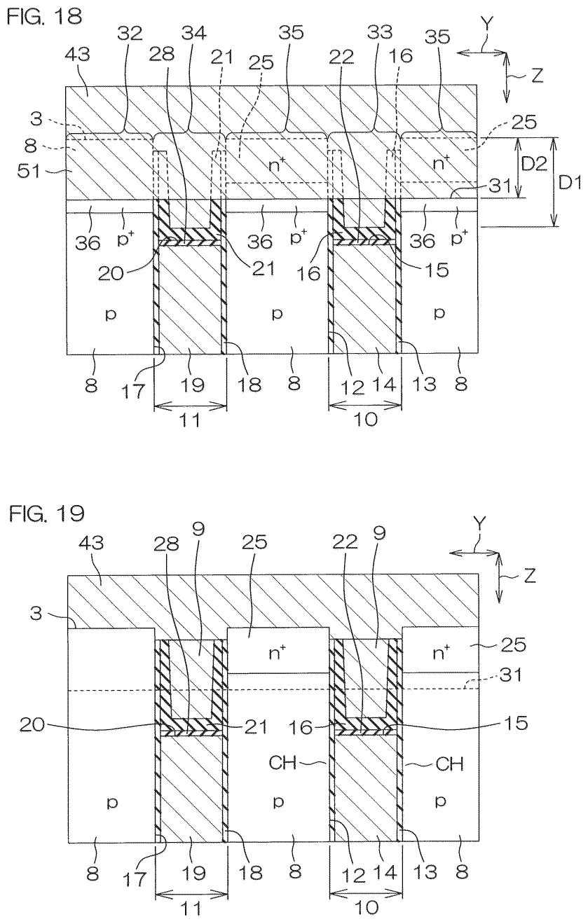

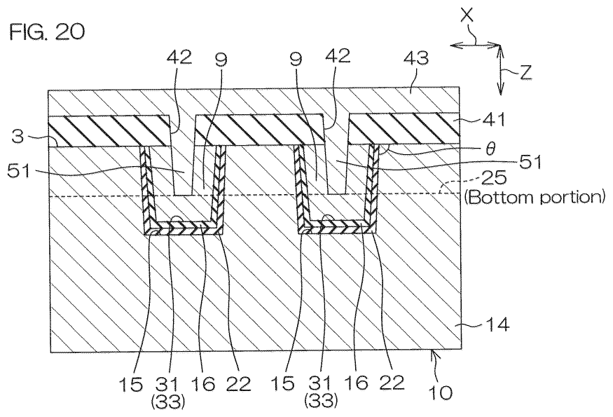

FIG. 18 is a schematic cross-sectional view illustrating a partial region of a semiconductor device 71 according to a second preferred embodiment of the present disclosure. FIG. 19 is a schematic cross-sectional view illustrating a partial region of the semiconductor device 71 according to the second preferred embodiment of the present disclosure. FIG. 20 is a schematic cross-sectional view illustrating a partial region of the semiconductor device 71 according to a second preferred embodiment of the present disclosure. FIG. 18 corresponds to the cross section of FIG. 5, FIG. 19 corresponds to the cross section of FIG. 6, and FIG. 20 corresponds to the cross section of FIG. 8. In the following, structures corresponding to the structures described with the semiconductor device 1 according to the first preferred embodiment shall be provided with the same reference signs and description thereof shall be omitted.

Referring to FIGS. 18 to 20, in the second preferred embodiment, the first depth D1 from the first principal surface 3 to the upper surface of the gate electrode layer 14 in the first intersection region 33 is deeper than the second depth D2 of the contact trench 31 in the contact region 35. Also, in the first intersection region 33, a laminated structure of the gate covering insulating layer 16 and the gate embedded body 9 is formed on the bottom wall of the contact trench 31. As a result, as shown in FIG. 20, the gate embedded body 9 is formed such as to straddle from one side to the other side of the first intersection region 33 in the first direction X and surrounds an emitter contact electrode layer 51 from three directions, that is, from both lateral sides in the first direction X and from below.

Also, in the first intersection region 33, the upper end portion of the gate electrode layer 14 is positioned on the second principal surface 4 side (the opposite side of the first principal surface 3) with respect to the bottom portion of an emitter region 25. Therefore, in the semiconductor device 71 according to the second preferred embodiment, the facing portion 40 illustrated in FIG. 7 does not exist, and the gate electrode layer 14 does not face the emitter region 25 via a gate insulating layer 13 near both sides of the first intersection region 33 in the first direction X.

As described above, even with the semiconductor device 71 according to the second preferred embodiment, the same effects as the effects described for the semiconductor device 1 can be exhibited. The semiconductor device 71 can be manufactured only by changing the depth of the gate electrode recess portion 15 and the depth of the emitter electrode recess portion 20 in the method for manufacturing the semiconductor device 1.

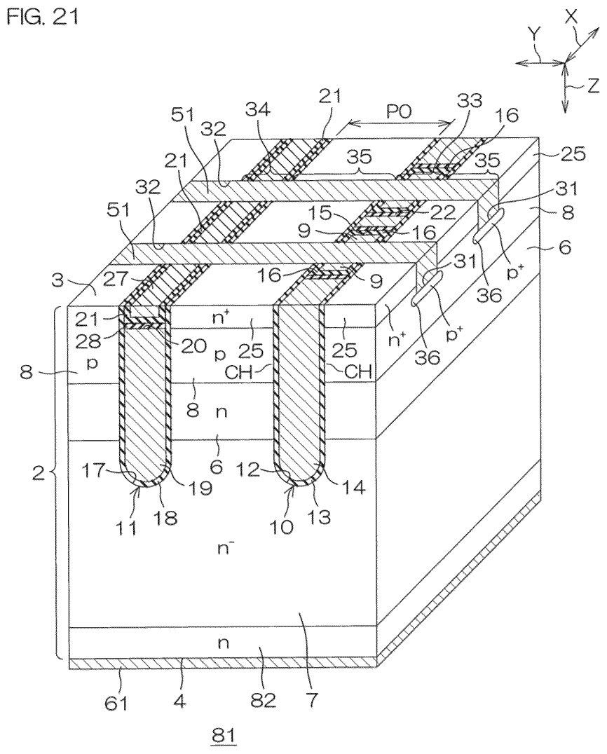

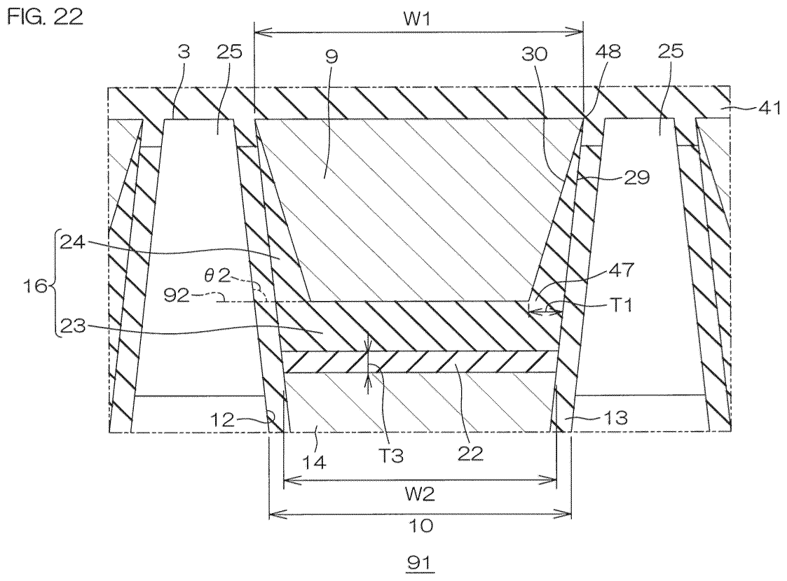

FIG. 21 is a schematic cross-sectional perspective view illustrating a partial region of a semiconductor device 81 according to a third preferred embodiment of the present disclosure. In the following, structures corresponding to the structures described with the semiconductor device 1 shall be provided with the same reference signs and description thereof shall be omitted.

With the semiconductor device 1 described above, an example in which the p-type collector region 5 is formed in the surface portion of the second principal surface 4 has been described. On the other hand, in the semiconductor device 81, instead of the p-type collector region 5, a drain region 82 of the n-type is formed in the surface portion of the second principal surface 4. Hence, the semiconductor device 81 has a basic form including a trench-gate type MISFET (Metal Insulator Semiconductor Field Effect Transistor). The description of the semiconductor device 1 above applies to a description of the semiconductor device 81 by reading “emitter” as “source” and by reading “collector” as “drain.”

As described above, even with the semiconductor device 81, the same effects as the effects described for the semiconductor device 1 can be exhibited. The semiconductor device 81 can be manufactured only by forming the n-type drain region 82 instead of the p-type collector region 5 and by changing the layout of each mask in the manufacturing method of the semiconductor device 1.

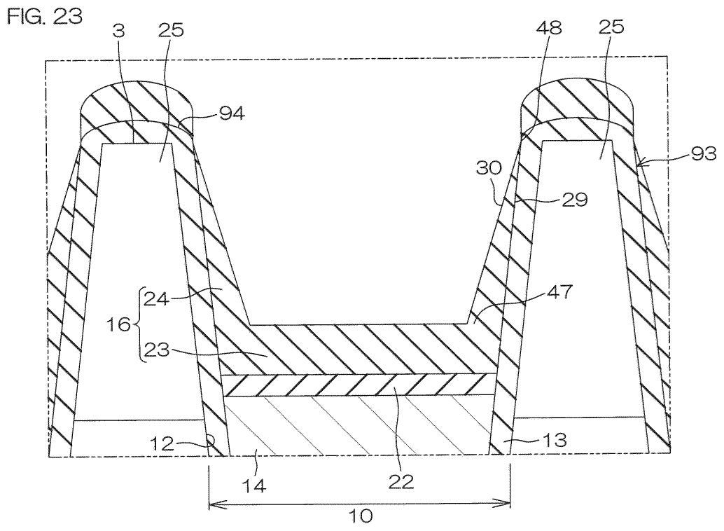

FIG. 22 is a schematic cross-sectional perspective view illustrating a partial region of a semiconductor device 91 according to a fourth preferred embodiment of the present disclosure. FIG. 23 is a diagram illustrating steps associated with the formation of the structure in FIG. 22. FIGS. 22 and 23 illustrate a cross section corresponding to FIG. 9 of the above-described semiconductor device 1. In the following, structures corresponding to the structures described with the semiconductor device I shall be provided with the same reference signs and description thereof shall be omitted.

With the semiconductor device 1 described above, an example in which the width W1 of the upper end portion of the gate embedded body 9 is narrower than the width W2 of the upper end portion of the gate electrode layer 14 has been described. On the other hand, in the semiconductor device 91, the width W1 of the upper end portion of a gate embedded body 9 is wider than the width W2 of the upper end portion of a gate electrode layer 14. When described in greater detail, the gate trench 12 is formed in a tapered shape in which a bottom area is smaller than an opening area. An angle θ2 formed by the side wall of the gate trench 12 with respect to a surface 92 parallel to the first principal surface 3 may be, for example, more than 80° and less than 90°, and preferably more than 85° and less than 90°. Therefore, in the depth direction of the gate trench 12, the width W1 of the gate embedded body 9 formed at a position closer to an opening end of the gate trench 12 than a depth position of the gate electrode layer 14 is wider than the width W2 of the gate electrode layer 14.

Also, with the semiconductor device 1 described above, an example in which the side portion 24 of the gate covering insulating layer 16 has the upper end portion 48 having the second thickness T2 thinner than the first thickness T1 of the lower end portion 47 has been described. On the other hand, in the semiconductor device 91, the second thickness T2 may be 0 (zero) by making an outer side surface 29 and an inner side surface 30 be in contact with each other at the upper end portion 48. The upper end portion 48 of the side portion 24 of the gate covering insulating layer 16 may be a sharp tip portion pointed upward.

As described above, even with the semiconductor device 91, the same effects as the effects described for the semiconductor device 1 can be exhibited. The semiconductor device 91 can be manufactured by forming the gate trench 12 by etching under the condition of realizing a tapered shape and forming the side portion 24 of the gate covering insulating layer 16 such as to have a tapered shape in the method for manufacturing the semiconductor device 1. Also, although not described in the above description, a mesa structure 93 (portion where the emitter region 25 and the like are formed) of the chip 2 formed on the lateral side of the gate trench 12 may have an upper end portion 94 which is trapezoidal in cross-sectional view and is formed in a round shape. The width W1 of the gate embedded body 9 can be made larger than the width W2 of the gate electrode layer 14 by forming the gate covering insulating layer 16 under the condition of realizing a tapered shape with respect to such a mesa structure 93.

Although preferred embodiments of the present disclosure have been described above, the present disclosure can be implemented in yet other preferred embodiments.

For example, in each of the preferred embodiments described above, a structure in which the conductivity types of the respective semiconductor portions are inverted may be adopted. That is, a p-type portion may be made to be of an n-type and an n-type portion may be made to be of a p-type.

With each of the preferred embodiments described above, an example in which chip 2 is constituted of a silicon monocrystal has been described. However, the chip 2 may include SiC. Also, the chip 2 may be constituted of an SiC monocrystal.

Thus, the preferred embodiments of the present disclosure in all respects are illustrative and not to be interpreted to be restrictive and are intended to include modifications in all respects.

The following appended features can be extracted from the descriptions in this Description and the drawings.

### APPENDIX 1-1

A semiconductor device (1, 71, 81) including:

a chip (2) having a first principal surface (3) on which a gate trench (12) extending in a first direction (X) is formed;

a body region (8) of a first conductivity type formed along a side wall of the gate trench (12) in a surface portion of the first principal surface (3);

a first impurity region (25) of a second conductivity type formed along the side wall of the gate trench (12) in a surface portion of the body region (8);

a gate insulating layer (13) formed on an inner wall of the gate trench (12);

a gate electrode (14) embedded in the gate trench (12) and facing the body region (8) and the first impurity region (25) across the gate insulating layer (13);

a surface insulating layer (41) formed on the first principal surface (3) such as to cover the gate electrode (14) and having a contact hole (42) led from a region on the gate trench (12) to the outside of the gate trench (12) along a second direction (Y) intersecting the first direction (X);

a contact electrode (51) electrically connected to the body region (8) and the first impurity region (25) through the contact hole (42) and led from the inside of the gate trench (12) to a surface portion of the first principal surface (3) through the side wall of the gate trench (12);

a covering insulating layer (16) covering the gate electrode (14) in the gate trench (12) and insulating the gate electrode (14) and the contact electrode (51) from each other; and

an embedded body (9) embedded in a region on the covering insulating layer (16) in the gate trench (12) and having an etching selectivity to the surface insulating layer (41).

### APPENDIX 1-2

The semiconductor device (1, 71, 81) according to Appendix 1-1, wherein the covering insulating layer (16) includes a bottom portion (23) covering an upper surface of the gate electrode (14) and a side portion (24) extending upward from the bottom portion (23) along the side wall of the gate trench (12).

### APPENDIX 1-3

The semiconductor device (1, 71, 81) according to Appendix 1-2, wherein the bottom portion (23) of the covering insulating layer (16) has a thickness of 150 nm or more and 300 nm or less.

### APPENDIX 1-4

The semiconductor device (1, 71, 81) according to Appendix 1-2 or Appendix 1-3, wherein the side portion (24) of the covering insulating layer (16) has a first thickness (T1) at a lower end portion (47) in a depth direction of the gate trench (12) and has a second thickness (T2) thinner than the first thickness (T1) at an upper end portion (48) in the depth direction of the gate trench (12).

### APPENDIX 1-5

The semiconductor device (1, 71, 81) according to any one of Appendix 1-2 to Appendix 1-4, wherein the side portion (24) of the covering insulating layer (16) has a tapered shape with an outer side surface (29) close to the side wall of the gate trench (12) and an inner side surface (30) opposite to the outer side surface (29) being inclined such as to approach each other from the lower end portion (47) toward the upper end portion (48) in cross-sectional view.

### APPENDIX 1-6

The semiconductor device (1, 71, 81) according to any one of Appendix 1-1 to Appendix 1-5, wherein a contact trench (31) formed in a surface portion of the first principal surface (3) such as to extend along the contact hole (42) and having a bottom wall (37, 38) and a side wall,

the body region (8) is formed at least along the bottom wall (37, 38) of the contact trench (31),

the first impurity region (25) is formed at least along the side wall of the contact trench (31), and

the contact electrode (51) is embedded in the contact trench (31) and connected to the body region (8) and the first impurity region (25) inside the contact trench (31).

### APPENDIX 1-7

The semiconductor device (1, 81) according to Appendix 1-6, wherein the contact trench (31) includes an intersection region (33) which intersects the gate trench (12) and a contact region (35) led from the intersection region (33) to the outside of the gate trench (12) and from which the body region (8) and the first impurity region (25) are exposed, and

a depth (D1) from the first principal surface (3) to the upper surface of the gate electrode (14) in the intersection region (33) is shallower than a depth (D2) from the first principal surface (3) to a bottom wall of the contact trench (31) in the contact region (35).

### APPENDIX 1-8

The semiconductor device (1, 81) according to Appendix 1-7, wherein the bottom portion (23) of the covering insulating layer (16) is exposed on the bottom wall (37) of the contact trench (31) in the intersection region (33), and

the embedded body (9) includes a pair of the embedded bodies (9) which are provided on both sides in the first direction (X) with respect to the intersection region (33) and sandwich the contact electrode (51) from both lateral sides in the first direction (X).

### APPENDIX 1-9

The semiconductor device (1, 81) according to Appendix 1-7 or Appendix 1-8, wherein the depth (D1) from the first principal surface (3) to the upper surface of the gate electrode (14) in the intersection region (33) is 1 μm or less.

### APPENDIX 1-10

The semiconductor device (71) according to Appendix 1-6, wherein the contact trench (31) includes an intersection region (33) which intersects the gate trench (12) and a contact region led from the intersection region (33) to the outside of the gate trench (12) and from which the body region (8) and the first impurity region (25) are exposed, and

a depth (D1) from the first principal surface (3) to the upper surface of the gate electrode (14) in the intersection region (33) is deeper than a depth (D2) from the first principal surface (3) to the bottom wall of the contact trench (31) in the contact region.

### APPENDIX 1-11

The semiconductor device (71) according to Appendix 1-10, wherein a laminated structure of the bottom portion (23) of the covering insulating layer (16) and the embedded body (9) is formed on the bottom wall (37) of the contact trench (31) in the intersection region (33), and

the embedded body (9) is formed such as to straddle from one side to the other side of the intersection region (33) in the first direction (X) and surround the contact electrode (51) from three directions, that is, from both lateral sides in the first direction (X) and from below.

### APPENDIX 1-12

The semiconductor device (1, 71, 81) according to any one of Appendix 1-1 to Appendix 1-11, wherein an etching selectivity of the embedded body (9) to the surface insulating layer (41) is 1.5 or more.

### APPENDIX 1-13

The semiconductor device (1, 71, 81) according to any one of Appendix 1-1 to Appendix 1-12, wherein the embedded body (9) is formed of the same material as the gate electrode (14).

### APPENDIX 1-14

The semiconductor device (1, 71, 81) according to any one of Appendix 1-1 to Appendix 1-12, wherein the surface insulating layer (41) is formed of silicon oxide, and the gate electrode (14) and the embedded body (9) are formed of polysilicon.

### APPENDIX 1-15

A manufacturing method for a semiconductor device (1, 71, 81), the method including: a step of forming a gate insulating layer (13) on an inner wall of a gate trench (12) of a semiconductor wafer (26) having a first principal surface (3) on which the gate trench (12) is formed;

a step of embedding a gate electrode (14) in the gate trench (12) after formation of the gate insulating layer (13);

a step of forming a recess portion (15) in the gate trench (12) by selectively removing the gate electrode (14) from an upper surface side;

a step of forming a covering insulating layer (16) in the recess portion (15) such as to cover an upper surface of the gate electrode (14);

a step of embedding an embedded body (9) in a region on the covering insulating layer (16) in the recess portion (15);

a step of forming a body region (8) along a side wall of the gate trench (12) by selectively implanting an impurity of a first conductivity type into a surface portion of the first principal surface (3);

a step of forming a first impurity region (25) along the side wall of the gate trench (12) by selectively implanting an impurity of a second conductivity type into a surface portion of the body region (8);

a step of forming a surface insulating layer (41) on the first principal surface (3) such as to cover the gate electrode (14) and the embedded body (9);

a step of selectively etching the surface insulating layer (41) to form a contact hole (42) intersecting the gate trench (12) such that the embedded body (9) and the first principal surface (3) are selectively exposed;

a step of forming a contact trench (31) in a surface portion of the first principal surface (3) by etching through the contact hole (42) such as to expose the body region (8) and the first impurity region (25); and

a step of forming a contact electrode (51) connected to the body region (8) and the first impurity region (25) such as to be embedded in the contact trench (31),

wherein the embedded body (9) is formed of a material having an etching selectivity with respect to the surface insulating layer (41).

1. A semiconductor device comprising:
a chip having a first principal surface on which a gate trench extending in a first direction is formed;
a body region of a first conductivity type formed along a side wall of the gate trench in a surface portion of the first principal surface;
a first impurity region of a second conductivity type formed along the side wall of the gate trench in a surface portion of the body region;
a gate insulating layer formed on an inner wall of the gate trench;
a gate electrode embedded in the gate trench and facing the body region and the first impurity region across the gate insulating layer;
a surface insulating layer formed on the first principal surface such as to cover the gate electrode and having a contact hole led from a region on the gate trench to the outside of the gate trench along a second direction intersecting the first direction;
a contact electrode electrically connected to the body region and the first impurity region through the contact hole and led from the inside of the gate trench to a surface portion of the first principal surface through the side wall of the gate trench;
a covering insulating layer covering the gate electrode in the gate trench and insulating the gate electrode and the contact electrode from each other; and
an embedded body embedded in a region on the covering insulating layer in the gate trench and having an etching selectivity to the surface insulating layer.

2. The semiconductor device according to claim 1, wherein the covering insulating layer includes a bottom portion covering an upper surface of the gate electrode and a side portion extending upward from the bottom portion along the side wall of the gate trench.

3. The semiconductor device according to claim 2, wherein the bottom portion of the covering insulating layer has a thickness of 150 nm or more and 300 nm or less.

4. The semiconductor device according to claim 2, wherein the side portion of the covering insulating layer has a first thickness at a lower end portion in a depth direction of the gate trench and has a second thickness thinner than the first thickness at an upper end portion in the depth direction of the gate trench.

5. The semiconductor device according to claim 2, wherein the side portion of the covering insulating layer has a tapered shape with an outer side surface close to the side wall of the gate trench and an inner side surface opposite to the outer side surface being inclined such as to approach each other from the lower end portion toward the upper end portion in cross-sectional view.

6. The semiconductor device according to claim 1, wherein a contact trench formed in a surface portion of the first principal surface such as to extend along the contact hole and having a bottom wall and a side wall,
the body region is formed at least along the bottom wall of the contact trench,
the first impurity region is formed at least along the side wall of the contact trench, and
the contact electrode is embedded in the contact trench and connected to the body region and the first impurity region inside the contact trench.

7. The semiconductor device according to claim 6, wherein the contact trench includes an intersection region which intersects the gate trench and a contact region led from the intersection region to the outside of the gate trench and from which the body region and the first impurity region are exposed, and
a depth from the first principal surface to the upper surface of the gate electrode in the intersection region is shallower than a depth from the first principal surface to a bottom wall of the contact trench in the contact region.

8. The semiconductor device according to claim 7, wherein the bottom portion of the covering insulating layer is exposed on the bottom wall of the contact trench in the intersection region, and
the embedded body includes a pair of the embedded bodies which are provided on both sides in the first direction with respect to the intersection region and sandwich the contact electrode from both lateral sides in the first direction.

9. The semiconductor device according to claim 7, wherein the depth from the first principal surface to the upper surface of the gate electrode in the intersection region is 1 μm or less.

10. The semiconductor device according to claim 6, wherein the contact trench includes an intersection region which intersects the gate trench and a contact region led from the intersection region to the outside of the gate trench and from which the body region and the first impurity region are exposed, and
a depth from the first principal surface to the upper surface of the gate electrode in the intersection region is deeper than a depth from the first principal surface to the bottom wall of the contact trench in the contact region.

11. The semiconductor device according to claim 10, wherein a laminated structure of the bottom portion of the covering insulating layer and
the embedded body is formed on the bottom wall of the contact trench in the intersection region, and the embedded body is formed such as to straddle from one side to the other side of the intersection region in the first direction and surround the contact electrode from three directions, that is, from both lateral sides in the first direction and from below.

12. The semiconductor device according to claim 1, wherein an etching selectivity of the embedded body to the surface insulating layer is 1.5 or more.

13. The semiconductor device according to claim 1, wherein the embedded body is formed of the same material as the gate electrode.

14. The semiconductor device according to claim 1, wherein the surface insulating layer is formed of silicon oxide, and
the gate electrode and the embedded body are formed of polysilicon.

15. A manufacturing method for a semiconductor device, the method comprising:
a step of forming a gate insulating layer on an inner wall of a gate trench of a semiconductor wafer having a first principal surface on which the gate trench is formed;
a step of embedding a gate electrode in the gate trench after formation of the gate insulating layer;
a step of forming a recess portion in the gate trench by selectively removing the gate electrode from an upper surface side;
a step of forming a covering insulating layer in the recess portion such as to cover an upper surface of the gate electrode;
a step of embedding an embedded body in a region on the covering insulating layer in the recess portion;
a step of forming a body region along a side wall of the gate trench by selectively implanting an impurity of a first conductivity type into a surface portion of the first principal surface;
a step of forming a first impurity region along the side wall of the gate trench by selectively implanting an impurity of a second conductivity type into a surface portion of the body region;
a step of forming a surface insulating layer on the first principal surface such as to cover the gate electrode and the embedded body;
a step of selectively etching the surface insulating layer to form a contact hole intersecting the gate trench such that the embedded body and the first principal surface are selectively exposed;
a step of forming a contact trench in a surface portion of the first principal surface by etching through the contact hole such as to expose the body region and the first impurity region; and
a step of forming a contact electrode connected to the body region and the first impurity region such as to be embedded in the contact trench,
wherein the embedded body is formed of a material having an etching selectivity with respect to the surface insulating layer.
